(19) United States
(12) Patent Application Publication
(10) Pub. No.: US 2009/0108415 A1
(43) Pub. Date: Apr. 30, 2009

(54) INCREASING ETCH SELECTIVITY DURING THE PATTERNING OF A CONTACT STRUCTURE OF A SEMICONDUCTOR DEVICE

(76) Inventors: Markus LENSKI, Dresden (DE); Stephan KRUEGEL, Reichenberg (DE); Andreas GEHRING, Dresden (DE)

Correspondence Address: WILLIAMS, MORGAN & AMERSON, 10333 RICHMOND, SUITE 1100, HOUSTON, TX, 77042, US

(21) Appl. No.: 12/107,293

(22) Filed: Apr. 22, 2008

(30) Foreign Application Priority Data
Oct. 31, 2007 (DE) 10 2007 052 050.8

(51) Int. Cl. H01L 23/58; H01L 21/311

(52) U.S. Cl. 257/649; 438/696; 257/E21.249; 257/E23.001

(57) ABSTRACT

By forming an intermediate etch stop material or by appropriately positioning an additional etch stop material in a spacer structure of a polysilicon line, the probability of exposing a shallow doped region of an active semiconductor region during a critical contact etch step for forming rectangular contacts may be significantly reduced. Thus, leakage current, which may conventionally be created by etching into shallow doped regions during the contact etch step, may be reduced.

### BACKGROUND OF THE INVENTION

1. Field of the Invention

Generally, the present disclosure relates to the field of semiconductor manufacturing, and, more particularly, to the formation of an interconnect structure having a contact plug for directly connecting a gate line with a drain/source region of a transistor.

2. Description of the Related Art

Semiconductor devices, such as advanced integrated circuits, typically contain a large number of circuit elements, such as transistors, capacitors, resistors and the like, which are usually formed in a substantially planar configuration on an appropriate substrate having formed thereon a crystalline semiconductor layer. Due to the large number of circuit elements and the required complex layout of modern integrated circuits, the electrical connections of the individual circuit elements may generally not be established within the same level on which the circuit elements are manufactured, but require one or more additional “wiring” layers, which are also referred to as metallization layers. These metallization layers generally include metal-containing lines, providing the inner-level electrical connection, and also include a plurality inter-level connections, which are also referred to as “vias,” that are filled with an appropriate metal and provide the electrical connection between two neighboring stacked metallization layers.

To establish the connection of the circuit elements with the metallization layers, an appropriate vertical contact structure is provided that connects to a respective contact region of a circuit element, such as a gate electrode and the drain/source regions of transistors, and to a respective metal line in the first metallization layer. The contact plugs and regions of the contact structure are formed in an interlayer dielectric material that encloses and passivates the circuit elements. In some circuit configurations, a connection of individual areas of a circuit element with other individual areas of the same or other circuit elements, such as a connection from a gate electrode or a polysilicon line to an active semiconductor region, such as a drain/source region, may be established by means of the contact structure rather than forming a specific metal connection in the first or a higher metallization level. One example in this respect is the wiring scheme of certain memory devices, such as SRAM (static random access memory) areas, which are frequently comprised of a plurality of transistors and act as fast intermediate storage cell array, also referred to as cache memories. In view of enhanced spatial efficiency of such memory arrays, the connections may partially be accomplished within the contact structure, for instance, by providing rectangular contact areas rather than square-shaped contact areas as are typically used for contact plugs connecting to individual contact areas. The rectangular contact areas may connect the gate electrode or polysilicon lines with an adjacent drain/source region.

During the formation of respective contact regions directly connecting individual contact regions of circuit elements, however, a plurality of issues may arise, in particular for highly advanced semiconductor devices having critical feature sizes of 100 nm and even less. With reference to FIGS. 1a-1b, a typical conventional process flow for forming respective contact regions for directly connecting polysilicon lines or gate electrodes with respective active semiconductor regions, i.e., drain/source regions, will be described in more detail in order to more clearly demonstrate the problems involved therein.

FIG. 1a schematically shows a semiconductor device 100, which may represent any circuit portion, in which a rectangular contact region may be formed so as to connect adjacent circuit regions. The semiconductor device 100 may comprise a substrate 101, which may represent any appropriate substrate, such as a bulk silicon substrate and the like. The substrate 101 has formed thereon a substantially crystalline semiconductor layer 102 on and in which respective circuit elements are formed, one of which is indicated as element 120. A trench isolation 103 may be formed within the semiconductor layer 102 to define an active semiconductor region 150, which is to be understood as a doped semiconductor region, in which at least a portion is configured in substantially the same way as a drain or source region of a field effect transistor of the device 100. Consequently, the active region 150 may comprise implanted areas 107, 107e, which may conveniently be referred to as drain/source regions 107 with respective extension regions 107e. Moreover, the device 100 may comprise a polysilicon line 104, which may be formed above the active region 150 and which may be separated therefrom by an insulation layer 105, wherein the polysilicon line 104 may be substantially formed according to design criteria as are also used for the formation of gate electrode structures in the device 100. On sidewalls of the polysilicon line 104, respective sidewall spacers 106 may be formed, which are typically comprised of silicon nitride. Respective metal silicide regions 108 may be formed on top of the polysilicon line 104 and in the drain/source region 107, and a contact etch stop layer 109, typically comprised of silicon nitride, may be formed on the active region 150 and the polysilicon line 104 including the sidewall spacers 106. Finally, an interlayer dielectric material 110 may be formed above the circuit element 120 represented by the polysilicon line 104 and the active region 150 so as to enclose and passivate the circuit element 120. In many cases, the interlayer dielectric material is comprised of silicon dioxide.

A typical process flow for forming the semiconductor device 100 as shown in FIG. 1a may comprise the following processes. The insulation layer 105 and the polysilicon line 104 may be formed on the basis of well-established oxidation, deposition, photolithography and etch techniques, wherein lateral dimensions of the polysilicon line 104 may be selected in accordance with device requirements, wherein, in sophisticated devices, the lateral dimension may be approximately 100 nm and even less. Thereafter, the sidewall spacers 106 may be formed by well-established deposition and anisotropic etch techniques, wherein, prior to and after the formation of the sidewall spacer 106, which may be comprised of a plurality of spacer elements, appropriate implantation processes may be performed in order to form the source/drain region 107 including the extension region 107e. At appropriate stages of the manufacturing process, the device may be annealed to activate the dopants in the regions 107, 107e and also to re-crystallize implantation-induced crystal damage. Next, the metal silicide regions 108 may be formed, for instance, by depositing an appropriate refractory metal and initiating a silicidation process on the basis of an appropriate heat treatment. After the removal of any excess material, the contact etch stop layer 109 may be formed on the basis of well-established plasma enhanced chemical vapor deposition (PECVD) techniques followed by the deposition of the interlayer dielectric material 110, which is typically comprised of silicon dioxide. After any planarization processes, such as chemical mechanical polishing (CMP) and the like, for providing a substantially planar surface of the interlayer dielectric material 110, an appropriate photolithography process may be performed on the basis of a corresponding photolithography mask in order to form a resist mask (not shown) having respective openings corresponding to respective rectangular contact openings to be formed above the polysilicon line 104 and the drain/source region 107 to establish a direct electric connection therebetween. Based upon a corresponding resist mask, an anisotropic etch process may be performed, which may then be stopped in and on the contact etch stop layer 109, requiring a high etch selectivity for the corresponding etch recipe between the etch stop layer 109 and the interlayer dielectric material 110 when etching through the silicon dioxide material of the layer 110. Subsequently, a further etch step may be performed to open the contact etch stop layer 109 in order to contact the polysilicon line 104, i.e., the respective metal silicide region 108 formed thereon, and the drain/source region 107, i.e., the corresponding metal silicide region 108 formed therein.

The patterning process of contact openings in the interlayer dielectric material 110 is one of the most critical process stages for various reasons. First, the contact openings are provided with minimum lateral size due to the reduced feature sizes of the circuit elements 120 and the contact areas thereof, thereby requiring sophisticated lithography techniques. Second, when forming contacts to the drain and source regions of transistors, i.e., to the level of the active region 150, and also to respective gate electrodes, i.e., to the height level of the polysilicon line 104, the thickness to be etched to these different height levels is different by the height of the polysilicon line 104, thereby demanding a high etch selectivity between the material of the etch stop layer 109 and the material of the layer 110 to avoid undue silicide erosion. Third, contact openings of increased size, at least in one lateral dimension, that is, in the case of the device 100 shown in FIG. 1a, the extension perpendicular to the drawing plane of FIG. 1a, may exhibit a different etch rate compared to “regular” contact openings formed in other contact areas of transistors, thereby contributing to a highly non-uniform etch progression of the anisotropic etch process. This means that the etch front may proceed with higher speed in the contact opening for the rectangular contact compared to the square-shaped openings of reduced lateral size connecting to individual contact areas. Thus, for this reason, the stop capabilities of the etch stop layer 109 may not suffice. For these reasons, the nitride spacers 106 may be exposed during the respective etch process and may be reduced, since the stop layer 109 may be substantially consumed within the rectangular opening due to the increased etch rate. During further post-etch processes and cleaning steps prior to filling in a conductive material, further material of the silicide may be consumed, while in the area of the spacers 106, which may have been completely removed, erosion of the exposed silicon of the region 107e, having a very shallow dopant profile, may occur. Consequently, during this etch process, the etch front may penetrate the region 107e, thereby possibly creating a short to the remaining active region 150 or at least providing a significant risk of increased leakage currents of the resulting electric connection, in particular when the region 107e is formed on the basis of recipes resulting in very shallow drain and source extension regions in transistors (not shown) formed above the active region 150 or other active regions.

FIG. 1b schematically shows the semiconductor device 100 after the completion of the above-described process sequence and after filling in an appropriate metal. Hence, the semiconductor device 100 comprises a contact region 112, which may be filled with a conductive material, such as tungsten, wherein, optionally, at sidewall portions 112S and bottom portions 112B, a conductive barrier material, such as titanium and the like, may be provided. Since the contact region 112 is connected to the respective metal silicide regions 108 of the polysilicon line 104 and the region 107, a direct electrical connection between these two device areas is established. Moreover, as previously indicated, the etch process for forming a respective contact opening in the interlayer dielectric material 110 and the contact etch stop layer 109 may have created a recess 113 in the region 107e, which may even extend into the active region 150 below the shallow region 107e, which may be referred to as a well region, thereby possibly creating a short or at least a current path for increased leakage currents.

As a result, the conventional technique may lead to increased leakage currents or even short circuits between portions 113 of the active region 150 that are inversely doped with respect to the regions 107, 107e, thereby significantly negatively affecting the performance of the device 100.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to a technique that enables the formation of reliable contact structures including a direct connection between a conductive line element and highly doped areas of an active semiconductor region, wherein an increased reliability with respect to short circuits and leakage currents may be achieved. For this purpose, the etch selectivity of a sidewall spacer structure during the patterning of respective contact openings may be increased by providing an additional etch stop material in a self-aligned manner. The additional etch stop material may be provided with high compatibility to conventional process strategies, while nevertheless resulting in a high etch resistivity for an etch chemistry used to form contact openings, for which a moderately high over-etch time may be required so as to etch to significantly different height levels within an interlayer dielectric material. Since the additional etch stop material may be provided in a self-aligned manner, additional process complexity, for instance associated with additional photolithography steps and the like, may be maintained at a low level while also substantially avoiding any negative impact of the additional etch stop material with respect to other device areas, such as transistors, which may also be formed in and above an active semiconductor region of interest.

One illustrative method disclosed herein comprises forming a first sidewall spacer portion for a conductive line, wherein the conductive line partially extends above an active region of a semiconductor device. The method further comprises forming an intermediate etch stop layer on the first sidewall spacer portion and forming a second sidewall spacer portion on the intermediate etch stop layer. The method further comprises forming a contact etch stop layer above the active region and forming an interlayer dielectric material above the contact etch stop layer. Finally, the method comprises etching a contact opening in the interlayer dielectric material using the contact etch stop layer and the intermediate etch stop layer as an etch stop.

A further illustrative method for forming a contact in an interlayer dielectric material of a semiconductor device is provided. The method comprises forming a first etch stop liner to cover an active region and a conductive line partially formed above the active region. Furthermore, a second etch stop liner is formed on the first etch stop liner, wherein the first and the second etch stop liners differ in their material composition. Additionally, the method comprises forming a sidewall spacer for the conductive line by depositing a spacer layer and patterning the spacer layer by an anisotropic etch process using the second etch stop liner as an etch stop. Furthermore, the method comprises forming a dielectric layer stack above the active region, wherein the dielectric layer stack comprises a contact etch stop layer and an interlayer dielectric material. Moreover, a contact opening is formed in the interlayer dielectric material using the contact etch stop layer and the first etch stop liner as an etch stop and the contact opening is finally filled with a conductive material.

An illustrative semiconductor device disclosed herein comprises an active semiconductor region and a conductive line that at least partially extends above a portion of the active semiconductor region. The semiconductor device further comprises a sidewall spacer of the conductive line, wherein the sidewall spacer comprises at least locally a first portion and a second portion comprised of silicon and nitrogen, wherein a silicon-to-nitrogen ratio is higher in the first portion compared to the second portion. The semiconductor device further comprises an interlayer dielectric layer stack formed on the conductive line at the active semiconductor region. Finally, the semiconductor device comprises a contact region formed in a portion of the interlayer dielectric layer stack and filled with a conductive material in order to electrically connect the conductive line and the active semiconductor region.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a conventional semiconductor device during various stages for manufacturing a contact region for directly connecting a polysilicon line and a highly doped region of an active semiconductor region in accordance with conventional techniques, thereby possibly resulting in increased leakage currents or short circuits;

FIGS. 2a-2g schematically illustrate cross-sectional views of a semiconductor device during various manufacturing stages in forming a rectangular contact between a conductive line and a highly doped portion of an active region on the basis of an intermediate etch stop material provided within a sidewall spacer structure according to illustrative embodiments;

FIGS. 2h-2j schematically illustrate cross-sectional views during various manufacturing stages for forming a sidewall spacer structure for conductive lines and gate electrode structures having an enhanced etch selectivity on the basis of an intermediate etch stop material according to still further illustrative embodiments; and

FIGS. 3a-3c schematically illustrate cross-sectional views of a semiconductor device during various manufacturing stages for forming a rectangular contact region on the basis of a sidewall spacer structure having increased etch selectivity by forming a self-aligned additional etch stop material according to still other illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the subject matter disclosed herein relates to a technique for the formation of contact regions, i.e., metal-filled regions within an interlayer dielectric material for electrically connecting respective contact regions of circuit elements, such as field effect transistors, polysilicon lines, active regions and the like, in a “direct fashion,” i.e., without an electrical connection via the first metallization layer, wherein an increased reliability during the formation of respective contact openings may be achieved due to the provision of an additional etch stop material, which may be provided in the form of an intermediate etch stop material or which may be provided in the form of an etch stop liner, wherein a self-aligned process sequence may enable a high degree of compatibility with conventional manufacturing strategies while also maintaining an influence of other device areas at a low level. That is, the additional etch stop material for enhancing the overall etch selectivity during the critical contact patterning process may be formed in a self-aligned manner, substantially without affecting other circuit elements, such as transistors and the like, which receive “regular” contacts during the formation of rectangular contacts in specific device areas. Consequently, undue silicon removal in critical device areas, such as doped portions of an active semiconductor region having a very shallow vertical dopant distribution, may be substantially avoided or at least be significantly reduced, thereby reducing the probability for creating enhanced leakage currents, which may directly translate into increased production yield for critical semiconductor devices including, for instance, static RAM areas, as previously explained. The additional etch stop material may, in some illustrative embodiments, be provided in the form of a silicon- and nitrogen-based material having a high degree of compatibility with standard silicon nitride spacers and contact etch stop layers, however, with a modified ratio of silicon-to-nitrogen in order to significantly modify the etch behavior of the additional etch stop material during an anisotropic etch process for forming a contact opening within an interlayer dielectric material, such as a silicon dioxide-based material, down to very different height levels, such as the top surface of a conductive line, such as a gate electrode structure and surface portions of the active regions having a configuration corresponding to drain and source regions of transistor elements.

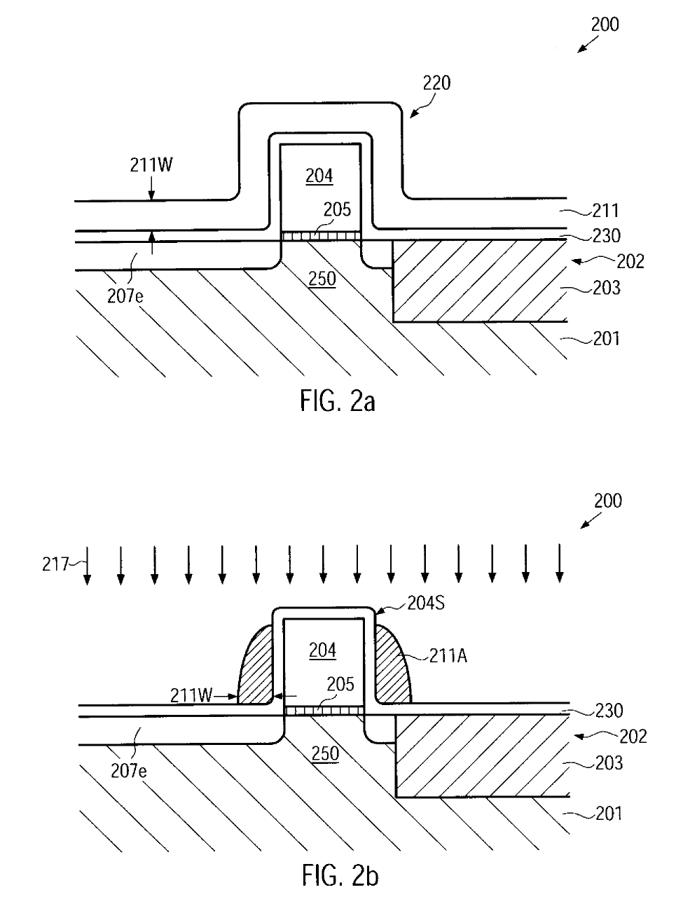

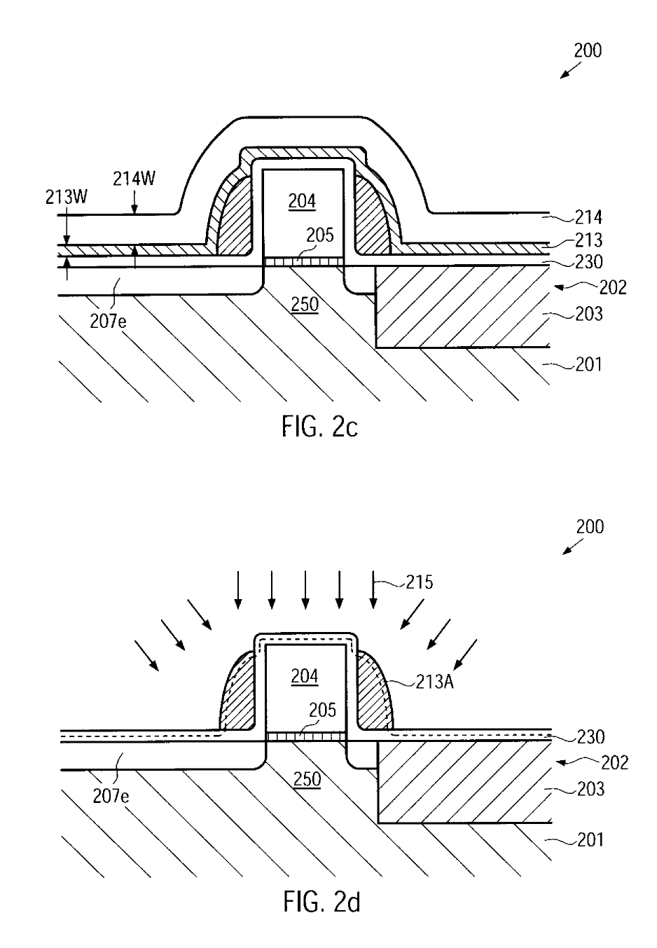

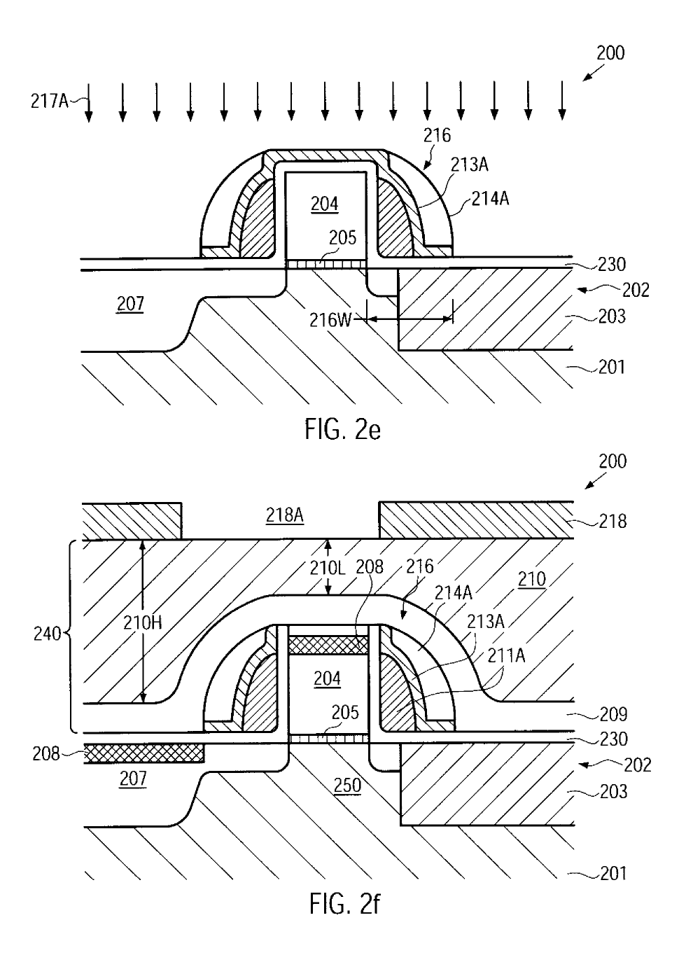

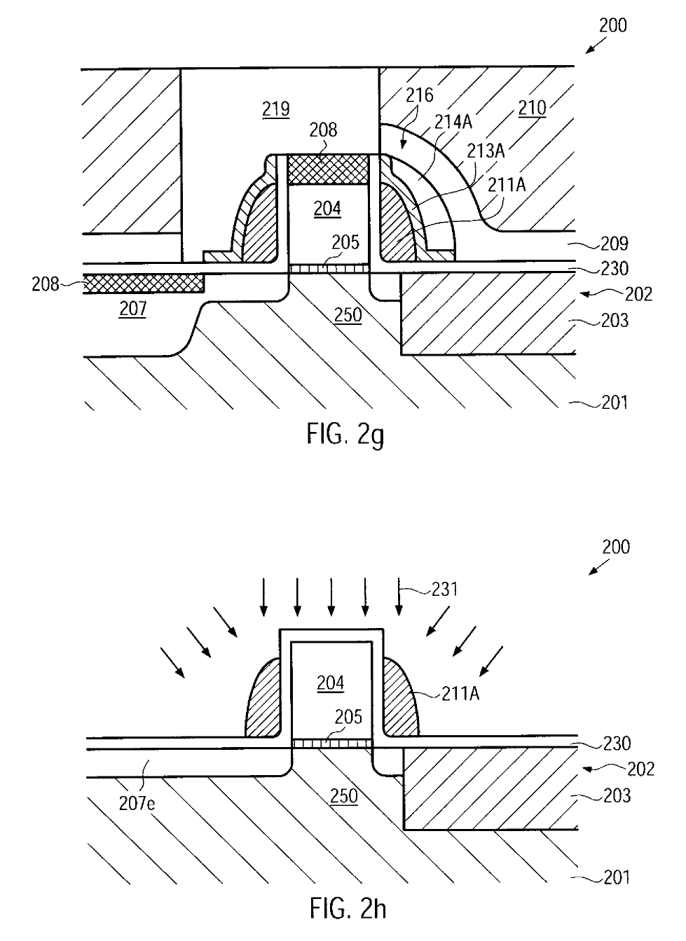

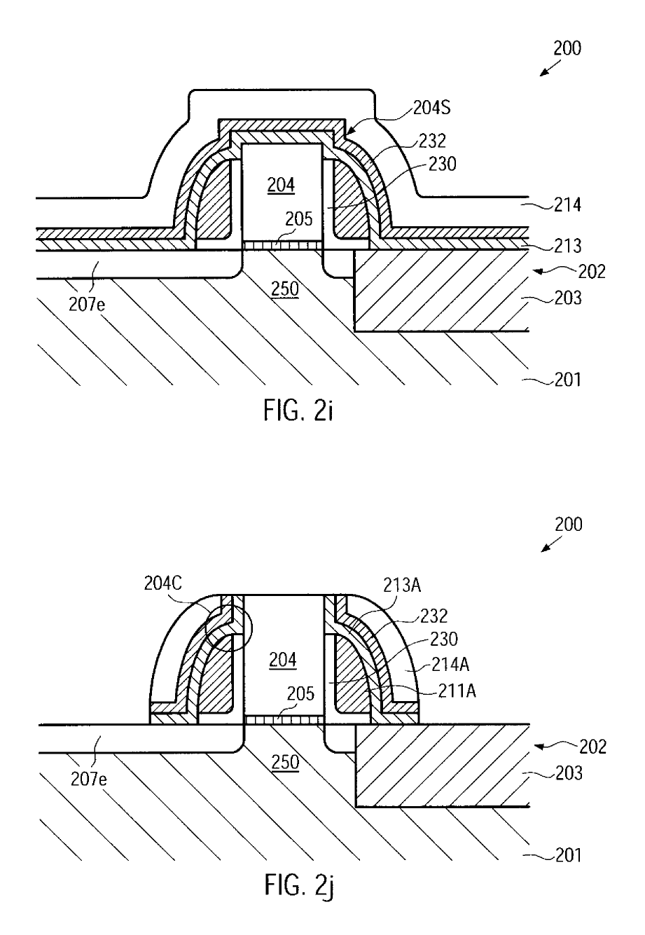

FIG. 2a schematically illustrates a cross-sectional view of a semiconductor device 200 which comprises a substrate 201 that may represent any appropriate carrier material for forming thereabove a semiconductor layer 202. For example, the semiconductor layer 202 may represent an upper portion of a substantially crystalline semiconductor material of the substrate 201, thereby providing a “bulk” configuration, i.e., a semiconductor configuration in which extended areas of the semiconductor layer 202 are electrically connected to the substrate material 201, wherein it should be appreciated that the bulk configuration may not necessarily extend across the entire substrate 201 but may be restricted to certain device areas in which a bulk configuration may be considered advantageous with respect to the electrical performance of specific circuit elements, such as transistors and the like. In other illustrative embodiments, the substrate 201 and the semiconductor layer 202 may represent an SOI-like (silicon-on-insulator) configuration, i.e., in this case, a buried insulating layer (not shown) may be provided below the semiconductor layer 202, thereby enabling a substantially complete dielectric isolation of a respective active semiconductor region that may be formed in the semiconductor layer 202. Moreover, in the manufacturing stage shown in FIG. 2a, the semiconductor device 200 may comprise an active region 250 within the semiconductor layer 202, wherein the active region 250 is to be understood as a semiconductor region in and above which may be formed one or more circuit elements, such as transistors, conductive lines and the like, wherein the conductivity within the active region 250 is to be patterned on the basis of appropriate vertical and lateral dopant profiles in accordance with device requirements. The active region 250 may be defined by appropriately designed isolation structures, such as a shallow trench isolation 203, which may be comprised of any appropriate dielectric material, as previously explained. In the embodiment shown, a circuit element 220 may be provided above at least a portion of the active region 250, wherein the circuit element 220 may represent a conductive line, the configuration of which may be similar to the configuration of any gate electrode structures of one or more transistor elements, which may also be formed in and above the active region 250. For convenience, any such transistor elements are not shown in FIG. 2a. The conductive line 220 may be comprised of polycrystalline silicon in a more-or-less doped configuration, depending on the previously performed processes. Furthermore, an insulation layer 205, which may have a similar configuration compared to gate insulation layers in other device areas, may separate the conductive line 204 from the material of the active region 250. In one illustrative embodiment, the active region 250 may represent an active region for forming transistor elements in combination with the conductive line 204 and may be part of a memory area in the form of a static RAM region.

As illustrated in FIG. 2a, in this manufacturing stage, the semiconductor device 200 may further comprise an etch stop liner 230 which may be comprised of, according to one illustrative embodiment, silicon dioxide, thereby providing a high degree of compatibility with conventional spacer formation regimes. Furthermore, a first spacer layer 211, which, in one illustrative embodiment, may be substantially comprised of silicon nitride, may be provided with a first thickness 211W that is selected to be less than a thickness as may be required for forming a spacer element so as to act as an efficient mask during the further processing of the semiconductor device 200, for instance, with respect to performing an ion implantation process, a silicidation process and the like. That is, a shallow doped region 207e, which may have a vertical extension corresponding to shallow PN junctions required for any transistor elements to be formed in the active region 250, may have been formed on the basis of any previously provided offset spacers (not shown) and the like, if required, while an additional lateral and vertical dopant profiling within the active region 250 has to be performed on the basis of an additional spacer element. However, contrary to conventional strategies, the spacer layer 211 may be provided with the reduced thickness 211W so as to allow the incorporation of an additional etch stop material after the patterning of the first spacer layer 211. As mentioned above, in some illustrative embodiments, the spacer layer 211 may be comprised of silicon nitride which may have a silicon-to-nitrogen ratio defined by the stoichiometric ratio according to the formula Si₃Ni₄ or less, depending on the degree of hydrogen incorporated therein and the like.

The semiconductor device 200 as shown in FIG. 2a may be formed on the basis of the following processes. After providing the substrate 201 and the semiconductor layer 202, appropriate manufacturing processes may be performed, as are also described with reference to the semiconductor device 100. Hence, after forming respective gate electrode structures, thereby also forming the polysilicon line 204 and the insulation layer 205, an appropriate implantation process may be performed, for instance on the basis of any offset spacers, to define the shallow dopant profile 207e. Next, the etch stop liner 230 may be formed by oxidation and/or deposition on the basis of well-established techniques. Thereafter, an appropriate thickness 211W may be selected for the spacer layer 211, which may then be deposited on the basis of well-established PECVD techniques, thereby controlling process parameters, such as gas flow rates of precursor materials, temperature, pressure, ion bombardment and the like, in order to establish the desired silicon-to-nitrogen ratio corresponding to the above-mentioned stoichiometric formula, wherein the nitrogen contents may also be less than specified by Si₃Ni₄ according to well-established recipes. Thus, the percentage of silicon atoms may be less than the percentage of nitrogen atoms in the first spacer layer 211.

FIG. 2b schematically illustrates the semiconductor device 200 during an anisotropic etch process 217 performed on the basis of a selective etch chemistry in order to remove material of the spacer layer 211 in a highly directional manner while using the etch stop liner 230 as an etch stop. The anisotropic etch process 217 may be performed on the basis of process parameters according to well-established recipes, wherein an etch time may be selected such that a certain degree of “over-etching” may be achieved, in which the material of the spacer layer 211 may be reliably removed from horizontal device portions and also from the etch stop liner 230 corresponding to an upper sidewall portion of the polysilicon line 204, as indicated by 204S. Consequently, after the anisotropic etch process 217, a first spacer portion 211A may be created that is recessed with respect to the polysilicon line 204 due to the over-etching time, thereby causing the exposed sidewall portion 204S. Moreover, the width of the first spacer portion 211A is substantially determined by the initial width 211W and the corresponding conditions during the process 217. In one illustrative embodiment, the first spacer portion 211A may not be used as an implantation mask for the further profiling of the dopant distribution within the active region 250 but may be used in combination with a second spacer portion to be provided in a later manufacturing stage to act as an appropriate mask during the further processing, such as a definition of a deep highly doped region, the creation of metal silicide portions and the like, as will be described later on. In other illustrative embodiments (not shown), the first spacer portion 211A may be formed in such a manner that it may be used as an effective implantation mask, if a highly complex lateral dopant profile may be required in respective transistor elements (not shown). Thus, in this case, after forming the first spacer portion 211A, a respective implantation process may be performed.

FIG. 2c schematically illustrates a cross-sectional view of the semiconductor device 200 in a further advanced manufacturing stage. As shown, a second spacer layer 214 may be formed above the active region and the circuit element 220, wherein, in one illustrative embodiment, the second spacer layer 214 may be comprised of substantially the same material composition as the first spacer layer 211. That is, in this case, the second spacer layer 214 may be comprised of a silicon nitride material having an appropriate silicon-to-nitrogen ratio corresponding to conventional strategies, which may be advantageous with respect to device and process requirements during the formation of transistor elements on the basis of well-established recipes. Hence, also in this case, the silicon-to-nitrogen ratio may be selected such that the percentage of silicon atoms is less than the percentage of nitrogen atoms in the second spacer layer 214. Furthermore, the semiconductor device 200 may comprise an intermediate etch stop material, which may be provided in the form of an intermediate etch stop layer 213, which may have a higher etch selectivity compared to the first spacer portion 211A and the second spacer layer 214 in view of an anisotropic etch process to be performed in a later manufacturing stage for defining a contact opening in an interlayer dielectric material. In one illustrative embodiment, the intermediate etch stop layer 213 may be comprised of silicon and nitrogen, wherein the material of the layer 213 may be provided in the form of a silicon-enriched silicon nitride material, that is, the percentage of silicon atoms within the layer 213 may be increased compared to the layer 214 and the spacer portion 211A, wherein the percentage of silicon may be higher than the percentage of nitrogen. That is, in this case, the material composition of the intermediate etch stop layer 213 may be represented by the formula SiₓNi_{y}, wherein x>y. Consequently, the intermediate etch stop layer 213 may exhibit significantly different etch characteristics compared to the layer 214 and the first spacer portion 211A, even if these components are also comprised of silicon and nitrogen, due to the increased amount of silicon incorporated into the intermediate etch stop layer 213.

In other illustrative embodiments, the intermediate etch stop layer 213 may be comprised of other materials, such as silicon carbide, nitrogen-containing silicon carbide and the like, as long as a different etch behavior during the subsequent contact etch process may be obtained compared to the components 214 and 211A.

The semiconductor device 200 as shown in FIG. 2c may be formed on the basis of the following processes. The intermediate etch stop layer 213 may be deposited on the basis of any appropriate deposition technique, such as PECVD and the like, wherein respective process parameters and precursor materials are selected so as to obtain the desired material composition and etch stop capability. For example, when the intermediate etch stop layer 213 is substantially comprised of silicon and nitrogen, the gas flow rates of respective precursor materials, deposition pressure, ion bombardment and the like may be selected so as to obtain the desired contents of silicon within the layer 213. If other materials are to be used, respective precursor materials in combination with appropriate process parameters may be determined and may be used for forming the layer 213. Furthermore, a thickness 213W of the layer 213 may be selected in combination with a thickness 214W of the spacer layer 214 to obtain a desired final spacer width in a subsequent process stage, wherein the width of the first spacer portion 211A may also be taken into consideration to obtain the desired masking effect of the finally established sidewall spacer structure. Hence, after the deposition of the intermediate etch stop layer 213, the second spacer layer 214 may be deposited, for instance, by selecting well-established process parameters for depositing a silicon nitride material, as previously explained. In one illustrative embodiment, the deposition of the intermediate etch stop layer 213 and the second spacer layer 214 may be performed in situ, that is, the same deposition chamber or at least the same deposition tool may be used, thereby avoiding any intermediate transport activities for the substrate 201, which may therefore result in the highly efficient overall process flow. In one illustrative embodiment, the layers 213 and 214 may be formed in a common deposition process by changing the deposition parameters after the desired thickness 213W is achieved in an initial phase of the overall deposition process. Hence, during the remaining deposition time, appropriate process parameters may be used for the layer 214.

FIG. 2d schematically illustrates the semiconductor device 200 according to a further illustrative embodiment in which, prior to the deposition of the second spacer layer 214, a treatment 215 may be performed to modify a surface portion of the first spacer portion 211A (FIG. 2b). For example, in one illustrative embodiment, the treatment 215 may include a plasma atmosphere with a less pronounced directionality of respective ionized particles, thereby modifying exposed surface portions of the semiconductor device 200. For instance, silicon may be incorporated into exposed surface portions, for instance in the first spacer portion 211A, thereby providing an increased percentage of silicon for providing an intermediate etch stop material in the form of a surface layer of the portion 211A. For convenience, a respective surface area is indicated as 213A, representing an intermediate etch stop material locally provided in the first portions 211A. It should be appreciated that a respective silicon content in the etch stop liner 230 may be less critical since this material may nevertheless provide the desired etch selectivity with respect to the second spacer layer 214, while, in other cases, exposed portions of the liner 230 may be removed and may be replaced by a further etch stop liner (not shown), for instance on the basis of oxidation, such as wet chemical oxidation, plasma induced oxidation and the like. Thereafter, the second spacer layer 214 may be deposited, as described above with reference to FIG. 2c.

FIG. 2e schematically illustrates the semiconductor device 200 in a further advanced manufacturing stage. As shown, the device 200 is subjected to a further anisotropic etch process 217A to remove material of the second spacer layer 214 (FIG. 2c), thereby creating a second spacer portion 214A. The anisotropic selective etch process 217A may be controlled on the basis of the etch stop liner 230 or on the basis of a newly provided etch stop liner, as is, for instance, explained with reference to FIG. 2d. Thus, after completion of the anisotropic etch process 217A, a spacer element 216 is obtained having the first portion 211A (FIG. 2b) and the second portion 214A with the intermediate etch stop material 213A. Furthermore, the thickness 216W of the spacer 216 may be defined by the width 213W and 214W (FIG. 2c) in combination with the initial width 211W (FIG. 2b) of the first spacer layer 211 (FIG. 2a). Thus, a high degree of process control may be obtained with respect to the final width 216W of the spacer 216, since, after defining the first spacer portion 211A, further adjustments may be performed on the basis of providing respective layer thicknesses 213W and 214W. For example, the width 213W may be selected to be approximately 5-15 nm, while the thickness 214W may be selected to be several tenths of nanometers, depending on the desired total width 216W. Moreover, as shown, the intermediate etch stop material 213A is embedded into the spacer 216 thereby providing a high degree of process and material compatibility with conventional strategies, since the first and second spacer portions 211A, 214A may be provided on the basis of well-established material compositions. There-after, the spacer 216 may be used as a mask for the further processing, that is, the dopant profile within the active region 211 may be defined on the basis of the spacer 216, thereby forming a highly doped deep region 207 which may correspond to deep drain and source regions in any transistor elements, which may be formed in the active region 250 concurrently with forming the circuit element 220 (FIG. 2a). Moreover, the spacer element 216 may be used as an efficient silicidation mask in order to create a metal silicide region in the highly doped region 207 and the polysilicon line 204 after exposing the respective surface portions thereof.

FIG. 2f schematically illustrates the semiconductor device 200 in a further advanced manufacturing stage with an interlayer dielectric layer stack 240, which may comprise a contact etch stop layer 209 and an interlayer dielectric material 210. The contact etch stop layer 209 may be comprised of a material having a moderately high etch selectivity with respect to the interlayer dielectric material 210, wherein silicon nitride may be used in accordance with well-established recipes, while the interlayer dielectric material 210 may be comprised of silicon dioxide, as previously explained. Moreover, a resist mask 218 is formed above the layer stack 240 and comprises an opening 218A that corresponds to a contact opening to be formed in the layer stack 240. In some illustrative embodiments, the opening 218A may represent a contact opening for connecting the polysilicon line 204 with the highly doped region 207, i.e., with respective metal silicide regions 208 formed on the highly doped region 207 and the polysilicon line 204. For example, in RAM areas, the opening 218A may be provided in the form of a rectangular opening, that is, other than “regular” square-shaped contact openings, which may individually connect to respective device areas, such as drain and source areas, gate areas and the like, of transistor elements that may also be formed in and above the active region 250.

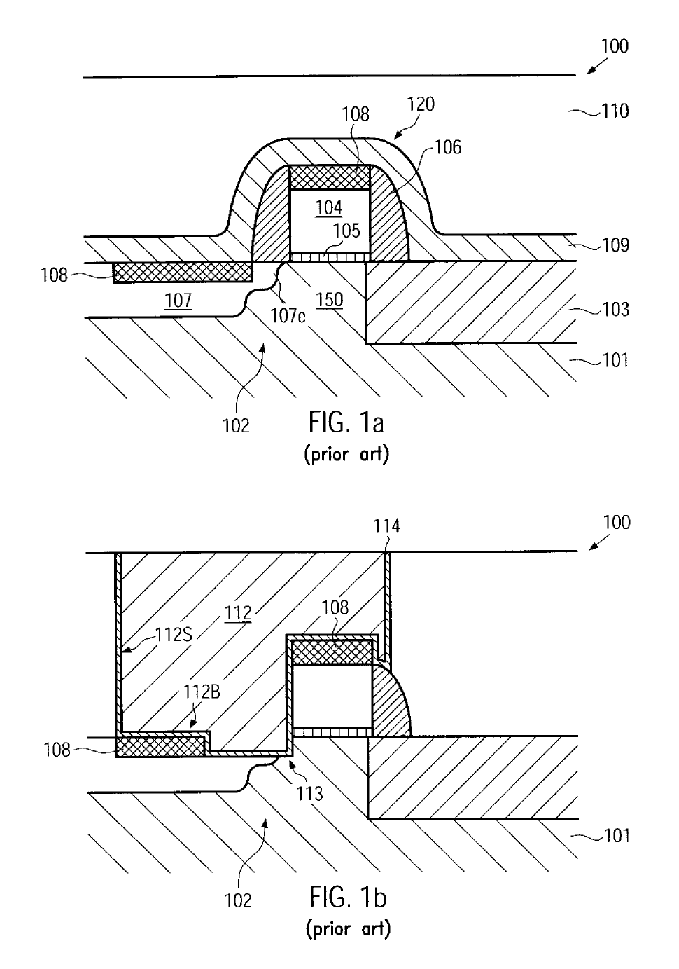

The semiconductor device 200 as shown in FIG. 2f may be formed on the basis of well-established techniques wherein the configuration of the spacer 216, i.e., of the first and second spacer portions 211A, 214A and the intermediate etch stop material 213A, provides a high degree of process compatibility with well-established techniques. Next, an anisotropic etch process may be performed on the basis of the resist mask 218 using a selective etch chemistry for removing material of the interlayer dielectric material 218 while using the moderately high etch selectivity of the layer 209. As previously explained, due to the very different height level 210L and 210H of the interlayer dielectric material 210, the moderate etch selectivity of the layer 209 may thus result in a significant material erosion and even in complete removal of the layer 209, thereby also exposing the spacer 216. Contrary to the conventional device as shown in FIGS. 1a-1b, the intermediate etch stop material 213A may provide significantly higher etch stop capability with respect to the etch chemistry under consideration, thereby substantially avoiding exposure of the silicon material of the shallow doped region 207E (FIG. 2d). For example, conventional silicon nitride materials may be used for the layer 209 and the spacer portion 211A, 214A, while a different material composition, such as a significantly increased fraction of silicon in a silicon nitride-based material, may provide the desired etch stop capabilities.

After forming a respective contact opening on the basis of the mask 218, further processing may be continued by filling in any appropriate conductive material, such as tungsten and the like.

FIG. 2g schematically illustrates the semiconductor device 200 after having completed the above-described process sequence. Hence, the device 200 may comprise a contact 219 formed within the layer stack 240 to connect the polysilicon line 204, i.e., the corresponding metal silicide region 208 formed therein, with the highly doped region 207, i.e., the respective metal silicide region 208. Furthermore, as shown, depending on the previous process, the second spacer portion 214A may have been locally removed during the subsequent patterning process, thereby exposing the intermediate etch stop material 213A. Consequently, the shallow doped region 207E (FIG. 2d) may be protected, thereby reducing the risk of generating increased leakage currents by shortening the respective PN junction.

With reference to FIGS. 2h-2j, further illustrative embodiments will be described in more detail, in which the enclosure of the first spacer portion 211A may be enhanced by providing an additional etch stop liner.

FIG. 2h schematically illustrates the semiconductor device 200 in a manufacturing stage which corresponds to the manufacturing stage also shown in FIG. 2b. That is, the first spacer portion 211A may have been created according to a process sequence as described with reference to FIG. 2b, wherein additional exposed portions of the etch stop liner 230 may be removed by an etch process 231 prior to forming the intermediate etch stop material 213A (FIG. 2g). For this purpose, the etch process 231 may include any appropriate process for selectively etching material of the layer 230 with respect to the polysilicon line 204 and material of the shallow doped region 207e. For example, a wet chemical etch process on the basis of hydrofluoric acid (HF) may be used, if the etch stop liner 230 is comprised of silicon dioxide. After the etch process 231, the intermediate etch stop material may be formed, for instance, on the basis of process techniques as described above.

FIG. 2i schematically illustrates the semiconductor device 200 in a further advanced manufacturing stage. As shown, the intermediate etch stop layer 213 is formed to cover exposed portions of the polysilicon line 204, the active region 250 and the first spacer portion 211A (FIG. 2h). That is, the intermediate etch stop layer 213 substantially completely encloses the first portion 211A even at the exposed sidewall portion 204S (FIG. 2b), thereby providing enhanced process reliability in later manufacturing stages when a contact opening is to be formed. Furthermore, a second etch stop liner 232 may be formed above the intermediate etch stop layer 213 and may be comprised of any appropriate material having a high etch selectivity with respect to the second spacer layer 214 in order to enable reliable patterning of the spacer layer 214. For example, the second etch stop liner 232 may be substantially comprised of the same material as the first etch stop liner 230. For instance, the liner 232 may be comprised of silicon dioxide. The spacer layer 214 may be formed on the basis of principles as described above.

FIG. 2j schematically illustrates the semiconductor device 200 after an anisotropic etch process for patterning the layer 214 in order to provide the second portion 214A, which is now separated from the first portion 211A by the intermediate etch stop layer 213 and the second etch stop liner 232. After the anisotropic etch process, an appropriate etch sequence may be performed to also remove exposed portions of the second etch stop liner 232 and the intermediate etch stop layer 213A, thereby preparing the device 200 for a subsequent silicidation process. The removal of exposed portions of the layers 232, 213A may be accomplished on the basis of well-established recipes, for instance by using hydrofluoric acid for the layer 232 when comprised of silicon dioxide, and hot phosphoric acid for the layer 213A when comprised of silicon-enriched silicon nitride. If other material combinations are used for the layers 232, 213A, respective etch chemistries may be appropriately selected. For example, even a substantially non-selective etch chemistry may be used for removing both the exposed portion of the layer 232 and of the layer 213A, wherein the respective etch chemistry may have a moderately high etch selectivity with respect to silicon material of the electrode line 204 and the shallow doped region 207e. A respective material removal of the second portion 214A may be appropriately taken into consideration when defining the width of the spacer 216, as is previously discussed with reference to FIG. 2e.

Thereafter, the further processing may be continued as described above. Consequently, during the critical contact etch process, the intermediate etch stop material 213A is provided in close contact with the sidewall 204C of the polysilicon line 204, thereby also enclosing the silicon dioxide-based material of the etch stop liner 230. Consequently, a possible material removal of the etch stop liner 230 may be efficiently suppressed by the material 213A, thereby even further enhancing the protective effect of the material 213A with respect to a possible exposure of the shallow doped region 207e located beneath the spacer structure 216. Hence, the overall process robustness may be further enhanced, thereby positively contributing to increased production yield.

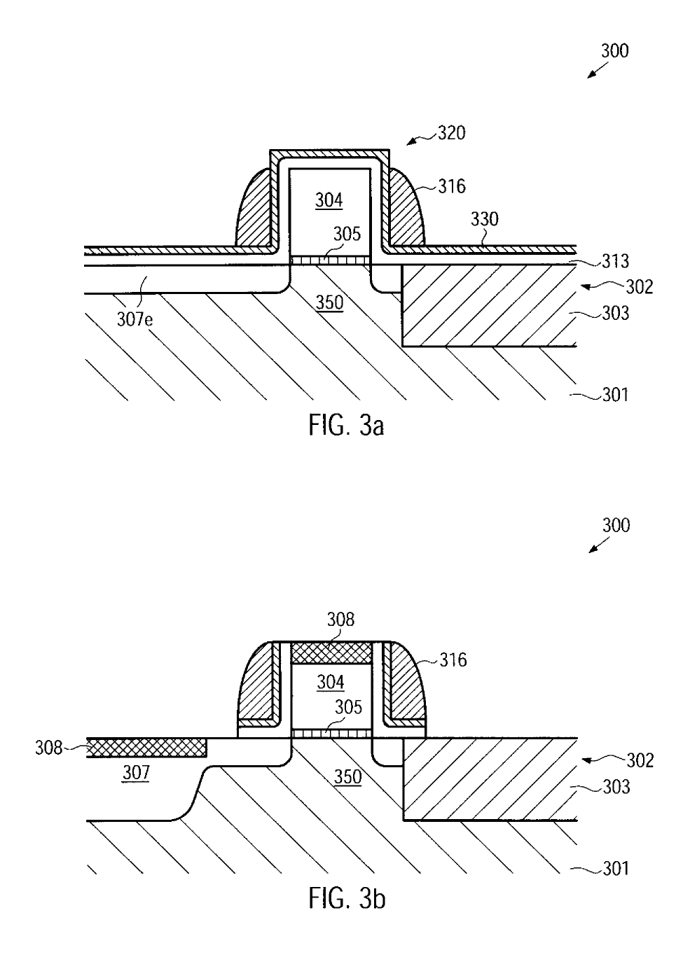

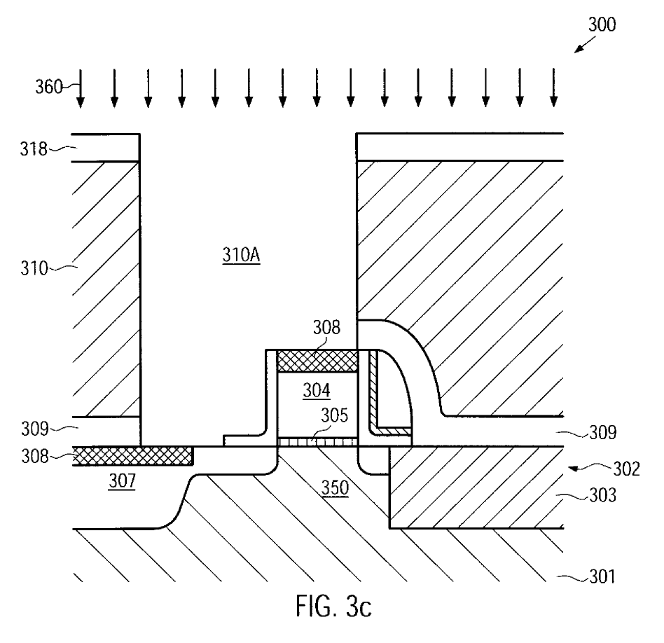

With reference to FIGS. 3a-3c, further illustrative embodiments will now be described, in which the etch selectivity of a spacer structure may be enhanced by providing an etch stop material prior to patterning a first portion of the spacer structure.

FIG. 3a schematically illustrates a semiconductor device 300 comprising a substrate 301 having formed thereabove a semiconductor layer 302, in which an active region 350 is defined by an isolation structure 303. Furthermore, a circuit feature 320, for instance in the form of a polysilicon line 304, is provided, which may be separated from the active region 350 by an insulation layer 305. With respect to the components described so far, the same criteria apply as previously explained with reference to the semiconductor devices 100 and 200. Hence, any further explanation thereof will be omitted.

Moreover, the semiconductor device 300 may comprise an etch stop layer 313, which may be comprised of an appropriate material that provides high etch selectivity during a critical contact etch step. In one illustrative embodiment, the etch stop layer 313 may be provided in the form of a silicon-enriched silicon nitride material, as previously explained with reference to the intermediate etch stop layer 213. Furthermore, the semiconductor device 300 may comprise an etch stop liner 330, for instance comprised of silicon dioxide, as previously explained with reference to the etch stop liner 230. Furthermore, a sidewall spacer 316 may be formed adjacent to the polysilicon line 304 in accordance with device requirements. That is, the sidewall spacer 316 may have a width that is appropriate for the further processing of the device 300, for instance with respect to further ion implantation processes, a silicidation sequence and the like.

The semiconductor device 300 as shown may be formed on the basis of similar processes, as previously explained with reference to the semiconductor device 200. Thus, the polysilicon line 304 may be formed on the basis of respective process techniques, wherein, other than in the embodiments described above, prior to forming a spacer layer, the etch stop layer 313 may be formed on the basis of process parameters selected to obtain the desired material composition. Thereafter, the etch stop liner 330 may be formed on the basis of any appropriate deposition techniques followed by the deposition of a spacer layer and a subsequent anisotropic etch process, which may be performed by using well-established techniques. It should be appreciated that well-established conventional process techniques may be used, wherein, however, during the patterning of the sidewall spacer 316, a respective layer thickness of the etch stop layer 313 may be taken into consideration so as to obtain the desired overall width of the spacer 316.

FIG. 3b schematically illustrates the semiconductor device 300 in a further advanced manufacturing stage. That is, after patterning the spacer elements 316, a further implantation may have been performed to define highly doped deep regions 307 followed by preparing the device 300 for a subsequent silicidation process. That is, exposed portions of the layers 330 and 313 may be removed, which may also be performed prior to the implantation process, depending on the process strategy. For this purpose, any appropriate etch sequence may be used, for instance plasma-assisted processes, wet chemical etch processes and the like may be employed. Thereafter, a silicidation sequence may be performed in order to obtain respective metal silicide regions 308 in the highly doped region 307 and the polysilicon line 304.

FIG. 3c schematically illustrates the semiconductor device 300 in a further advanced manufacturing stage. As shown, the device 300 may comprise a contact etch stop layer 309 followed by an interlayer dielectric material 310 and a resist mask 318. Furthermore, the device 300 is subjected to an etch process 360 for forming a contact opening 310A in the dielectric materials of the layers 310 and 309. As previously explained, during the etch process 360, the contact etch stop layer 309 may not provide the required etch selectivity, thereby also exposing the spacer 316 to the etch chemistry, wherein, however, due to the increased etch resistivity of the etch stop layer 313A, an exposure of the shallow doped region 307e (FIG. 3a) may be substantially prevented, thereby providing the advantages as described above.

As a result, the subject matter disclosed herein provides enhanced techniques for the formation of contact openings and respective contact structures for directly connecting a contact area for circuit elements with a highly doped portion of an active semiconductor region with a significantly reduced probability of exposing a shallow doped area of the active region during the contact etch step. For this purpose, the etch selectivity of a spacer structure may be increased by appropriately positioning a material of enhanced etch selectivity therein in a self-aligned manner, thereby ensuring a high degree of process compatibility with well-established CMOS process strategies. In some illustrative embodiments, the material of increased etch stop capabilities may be provided on the basis of a silicon nitride material wherein, however, the fraction of silicon may be significantly increased, thereby providing the desired enhanced etch stop capabilities. Moreover, well-established deposition techniques may be used wherein, in some cases, the deposition of the additional etch stop material and the deposition of a spacer layer may be performed in a common deposition process. Furthermore, in some illustrative aspects, the self-aligned provision of the additional etch stop material may be accomplished on the basis of a surface treatment, such as a plasma treatment, an implantation process, for instance using a tilted implantation sequence, and the like. Furthermore, in some aspects, a substantially complete enclosure of a portion of the spacer structure may be accomplished by providing the additional etch stop material directly on exposed surface areas of the polysilicon line. Hence, the probability of creating leakage currents, for instance in sophisticated RAM areas of semiconductor devices, may be reduced, thereby also enhancing production yield and product reliability.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a first sidewall spacer portion for a conductive line, said conductive line partially extending above an active region of a semiconductor device;
forming an intermediate etch stop layer on said first sidewall spacer portion;
forming a second sidewall spacer portion on said intermediate etch stop layer;
forming a contact etch stop layer above said active region;
forming an interlayer dielectric material above said contact etch stop layer; and
etching a contact opening in said interlayer dielectric material using said contact etch stop layer and said intermediate etch stop layer as an etch stop.

2. The method of claim 1, wherein said contact opening is formed so as to connect to said conductive line and a portion of said active region.

3. The method of claim 1, wherein said intermediate etch stop layer and said first and second sidewall spacer portions are formed on the basis of silicon and nitrogen.

4. The method of claim 3, wherein said intermediate etch stop layer comprises a higher fraction of silicon compared to said first and second sidewall spacer portions.

5. The method of claim 1, wherein forming said first sidewall spacer portion comprises depositing an etch stop liner, depositing a spacer layer and anisotropically etching said spacer layer to expose said etch stop liner on said conductive line and an upper sidewall portion thereof.

6. The method of claim 5, wherein said intermediate etch stop layer is formed by deposition after exposing said etch stop liner.

7. The method of claim 5, wherein said intermediate etch stop layer is formed by surface treatment of said first sidewall spacer portion after exposing said etch stop liner.

8. The method of claim 1, further comprising establishing a dopant distribution in said active region by using said conductive line as an implantation mask during a first implantation process and a second implantation process, wherein said first implantation process is performed prior to forming said first sidewall spacer portion and said second implantation process is performed after forming said second sidewall spacer portion.

9. The method of claim 8, wherein said first and second sidewall spacer portions are formed without performing an intermediate implantation process in said active region.

10. The method of claim 1, wherein forming said second sidewall spacer portion comprises depositing a second spacer layer on said intermediate etch stop layer and anisotropically etching said second spacer layer and an exposed portion of said intermediate etch stop layer.

11. The method of claim 10, wherein said intermediate etch stop layer and said second spacer layer are formed in situ.

12. The method of claim 10, further comprising filling said contact opening with a metal-containing material to form a contact connecting said conductive line with a highly doped portion of said active region.

13. The method of claim 1, further comprising forming a second etch stop liner on said intermediate etch stop layer and forming said second sidewall spacer portion by using said second etch stop liner as an etch stop.

14. A method of forming a contact in an interlayer dielectric material of a semiconductor device, the method comprising:
forming a first etch stop liner so as to cover an active region and a conductive line partially formed above said active region;
forming a second etch stop liner on said first etch stop liner, said first and second etch stop liners differing in material composition;
forming a sidewall spacer for said conductive line by depositing a spacer layer and patterning said spacer layer by an anisotropic etch process using said second etch stop liner as an etch stop;
forming a dielectric layer stack above said active region, said dielectric layer stack comprising a contact etch stop layer and an interlayer dielectric material;
forming a contact opening in said interlayer dielectric material using said contact etch stop layer and said first etch stop liner as an etch stop; and
filling said contact opening with a conductive material.

15. The method of claim 14, further comprising forming an etch stop layer above said active region, said etch stop layer covering an area that corresponds to an area of said active region that is covered by said conductive material.

16. The method of claim 14, wherein said first etch stop liner is comprised of silicon and nitrogen.

17. The method of claim 16, wherein said sidewall spacer is formed of silicon and nitrogen and wherein a silicon-to-nitrogen ratio in said sidewall spacer is less than in said first etch stop liner.

18. The method of claim 14, wherein said contact is formed so as to electrically connect to said conductive line and a highly doped portion of said active region.

19. The method of claim 14, further comprising forming a highly doped region in said active region and forming a metal silicide region in said highly doped region on the basis of said sidewall spacer.

20. A semiconductor device comprising:
an active semiconductor region;
a conductive line at least partially extending above a portion of said active semiconductor region;
a sidewall spacer of said conductive line, said sidewall spacer comprising at least locally a first portion and a second portion comprised of silicon and nitrogen, a silicon-to-nitrogen ratio being higher in said first portion compared to said second portion;
an interlayer dielectric layer stack formed on said conductive line and said active semiconductor region; and
a contact region formed in a portion of said interlayer dielectric layer stack and filled with a conductive material to electrically connect said conductive line and said active semiconductor region.

21. The semiconductor device of claim 20, wherein said first portion is provided as an intermediate layer, and wherein said second portion is provided as a first spacer portion and a second spacer portion separated by said intermediate layer.

22. The semiconductor device of claim 20, further comprising an etch stop liner located between said first and second portions, said etch stop liner being comprised of a material having a high etch selectivity with respect to said first and second portions.

23. The semiconductor device of claim 22, wherein said etch stop liner and a portion of said interlayer dielectric layer stack are comprised of silicon dioxide.
